(19) United States
(12) Patent Application Publication
(10) Pub. No.: US 2011/0057196 A1
(43) Pub. Date: Mar. 10, 2011

(54) GaN HEMT with Nitrogen-Rich Tungsten Nitride Schottky Gate and Method of Forming the Same

(75) Inventors: Edward Yi Chang, Baoshan Township (TW); Chung-Yu Lu, Taoyuan City (TW)

(73) Assignee: NATIONAL CHIAO TUNG UNIVERSITY, Hsinchu (TW)

(21) Appl. No.: 12/683,871

(22) Filed: Jan. 7, 2010

(30) Foreign Application Priority Data
Sep. 4, 2009 (TW) 98129929

(51) Int. Cl. H01L 29/20; H01L 29/778; H01L 21/335

(52) U.S. Cl. 257/76; 257/194; 438/172; 257/E29.246; 257/E29.089; 257/E21.403

(57) ABSTRACT

A GaN HEMT with Schottky gate is disclosed. The GaN HEMT sequentially has a GaN layer, an AlGaN layer, and a Schottky gate on a substrate, and a source and a drain on two sides of the Schottky gate. The Schottky gate is made by a material of nitrogen-rich tungsten nitride, which has a nitrogen content of about 0.5 molar ratio.

### CROSS-REFERENCE TO RELATED APPLICATION

This application claims the priority benefit of Taiwan application serial no. 98129929, filed Sep. 4, 2009, the full disclosure of which is incorporated herein by reference.

### BACKGROUND

1. Technical Field

The disclosure relates to a high electron mobility transistor (HEMT) having a Schottky gate. More particularly, the disclosure relates to a GaN HEMT with a nitrogen-rich tungsten nitride Schottky gate.

2. Description of Related Art

Most conventional GaN HEMTs use Ni metal to be their Schottky gate. Ni has a high work function of about 5.15 eV. Therefore, Ni can form a good Schottky gate on the top surface of AlGaN/GaN heterostructures. Since the GaN HEMT has high break down voltage and high energy band gap, the GaN HEMT can be operated under high-voltage and high-current environment. However, if the GaN HEMT uses Ni as its Schottky gate, the above properties are often degraded.

The reason for the degradation is that Ni diffuses into the AlGaN/GaN heterostructures in an anneal process under 600° C., and the electron transferring properties are thus changed. After aging the HEMT by applying high current and positive bias, the current leakage of the Ni Schottky gate is increased. Consequently, the break down voltage of the HEMT is decreased, and the HEMT is finally failed. Therefore, the operational environment and condition of the GaN HEMT is largely limited.

### SUMMARY

Accordingly, a GaN HEMT with a nitrogen-rich tungsten nitride Schottky gate is provided. The GaN HEMT comprises a GaN layer, an AlGaN layer, and a Schottky gate on a substrate, and a source and a drain on two sides of the Schottky gate. The Schottky gate is made by a material of nitrogen-rich tungsten nitride, which has a nitrogen content of about 0.5 molar ratio.

According to an embodiment, the nitrogen-rich tungsten nitride above is W_{0.52}N_{0.48}.

Furthermore, a method of forming the above GaN HEMT with a nitrogen-rich tungsten nitride Schottky gate is also provided.

### BRIEF DESCRIPTION OF THE DRAWINGS

FIGS. 1A-1B are XPS spectra of the nitrogen 1s orbital and the tungsten 4f orbital, respectively.

FIG. 2 shows XRD spectra of W_{0.52}N_{0.48}, W₂N, and W, from top to bottom.

FIG. 3 is UV photoemission spectrum of W_{0.52}N_{0.48}.

FIGS. 4A-4C are cross-sectional diagrams of a process for fabricating GaN HEMT according to an embodiment of this invention.

FIG. 5 is a diagram showing the relationship between the nitrogen content of the tungsten nitride gate and the Schottky barrier height of the GaN HEMT.

FIGS. 6A-6B are diagrams showing the aging test's result of the HEMTs having a nitrogen-rich tungsten nitride gate or Ni/Au gate under the test conditions described in the specification.

FIG. 7 is the testing result of the thermal stability of the HEMT having the nitrogen-rich tungsten nitride gate under the test conditions described in the specification.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

According to an embodiment, nitrogen-rich tungsten nitride is used to replace the nickel metal to be the Schottky gate of a HEMT to obtain a Schottky contact with good thermal stability and good aging resistance. According to an example, the molar ratio of the nitrogen-rich tungsten nitride is about 0.5.

Method Of Preparing High Nitrogen-Rich Tungsten Nitride

According to an embodiment, the above nitrogen-rich tungsten nitride is formed by reactive sputtering, such as direct-current (DC) magnetron reactive sputtering. According to an example, a tungsten target having a purity of 99.99% was used. The pressure in the chamber of the reactive sputtering was reduced to 1×10⁻⁶ Torr to remove the contaminant in the chamber prior to the sputtering. Then, the DC power of the sputtering apparatus was fixed at 30watt. Mixture of nitrogen and argon was directed into the chamber to start the reactive sputtering for depositing tungsten nitride film. The flow ratio of the nitrogen-to-argon (N₂/Ar) was controlled at 0.5 to control the nitrogen content of the tungsten nitride film. During the sputtering, the pressure in the chamber was about 5 mTorr.

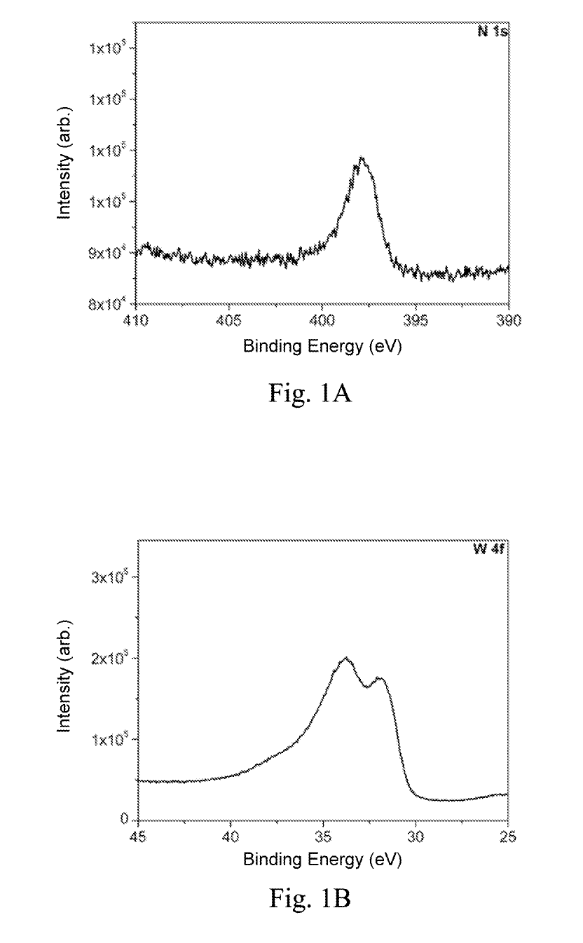

According to X-ray photoelectron spectroscopy (XPS), the composition of the tungsten nitride film was about W_{0.52}N_{0.48} when the flow ratio of the nitrogen to the argon was 0.5. FIGS. 1A-1B are XPS spectra of the nitrogen 1s orbital and the tungsten 4f orbital, respectively. The formula, W_{0.52}N_{0.48}, was obtained by calculating the ratio of the integrated area under the nitrogen 1s peak and the tungsten 4f peak.

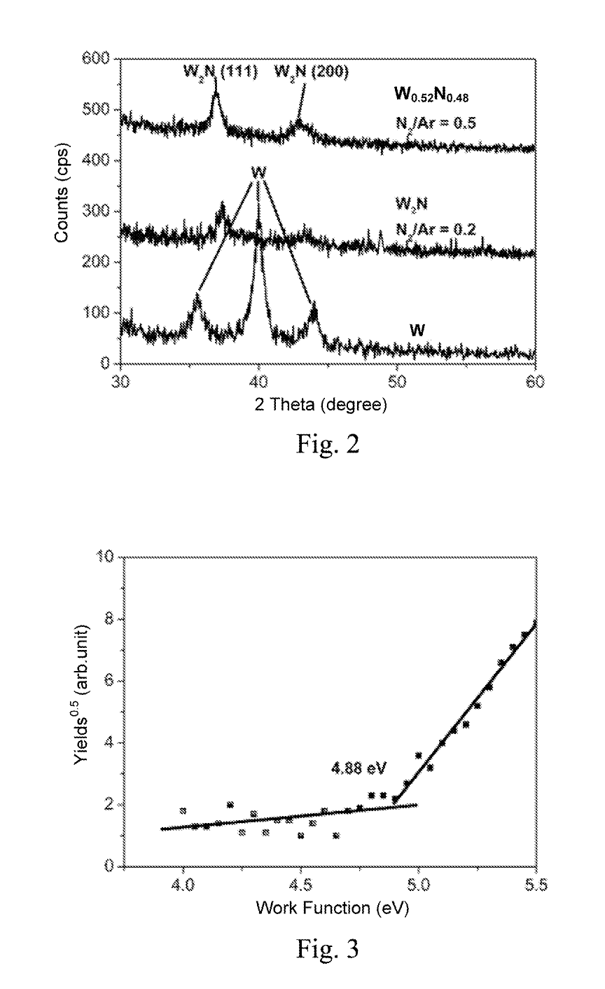

According to the X-ray diffraction (XRD) spectrum, the phase of the W_{0.52}N_{0.48} is very similar to the phase of the stoichiometric W₂N. FIG. 2 shows XRD spectra of W_{0.52}N_{0.48}, W₂N, and W, from top to bottom. In FIG. 2, no tungsten's XRD peaks were shown in the XRD spectra of W_{0.52}N_{0.48} or W₂N, but the XRD spectra were very similar for W_{0.52}N_{0.48} and W₂N. The only difference was that the W₂N peaks of the W_{0.52}N_{0.48} shifted to lower angles. This phenomenon indicated that the excessive nitrogen atom of W_{0.52}N_{0.48} might locate in the interstitial site of the lattice of W₂N to expand the W₂N lattice. Therefore, the lattice structure of the W₂N was not changed by the excess nitrogen, but only the lattice size was changed by the excessive nitrogen of W_{0.52}N_{0.48}.

FIG. 3 is UV photoemission spectrum of W_{0.52}N_{0.48}. In FIG. 3, the obtained work function of W_{0.52}N_{0.48} was about 4.88 eV. Although the work function of W_{0.52}N_{0.48} was slightly smaller than the work function of nickel metal (5.15 eV), the work function of W_{0.52}N_{0.48} was larger than the work function of W₂N (4.5 eV). Therefore, the work function of tungsten nitride can be increased by increasing the nitrogen content.

Fabricating Method Of GaN HEMT

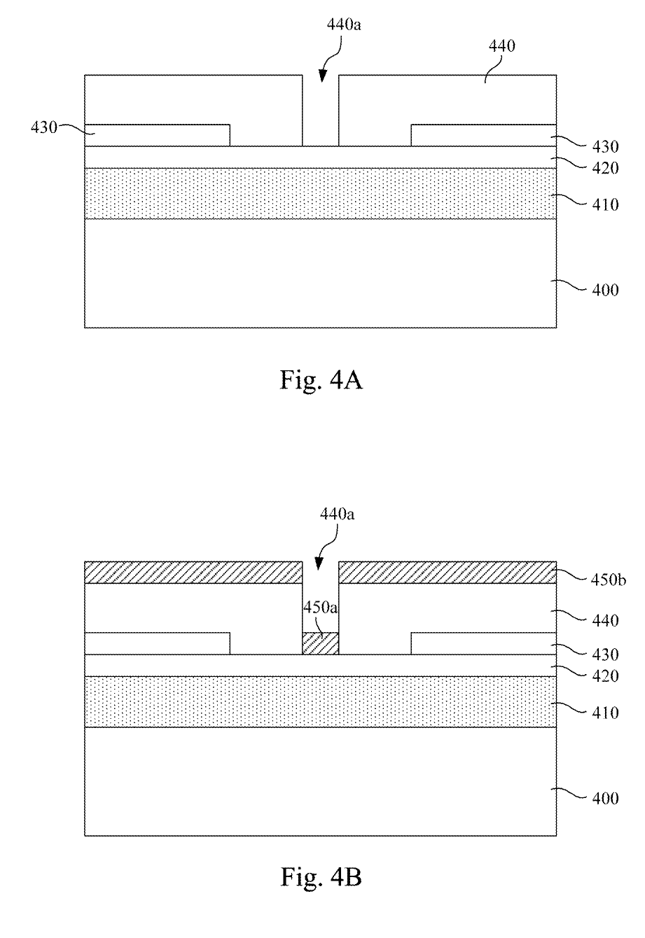

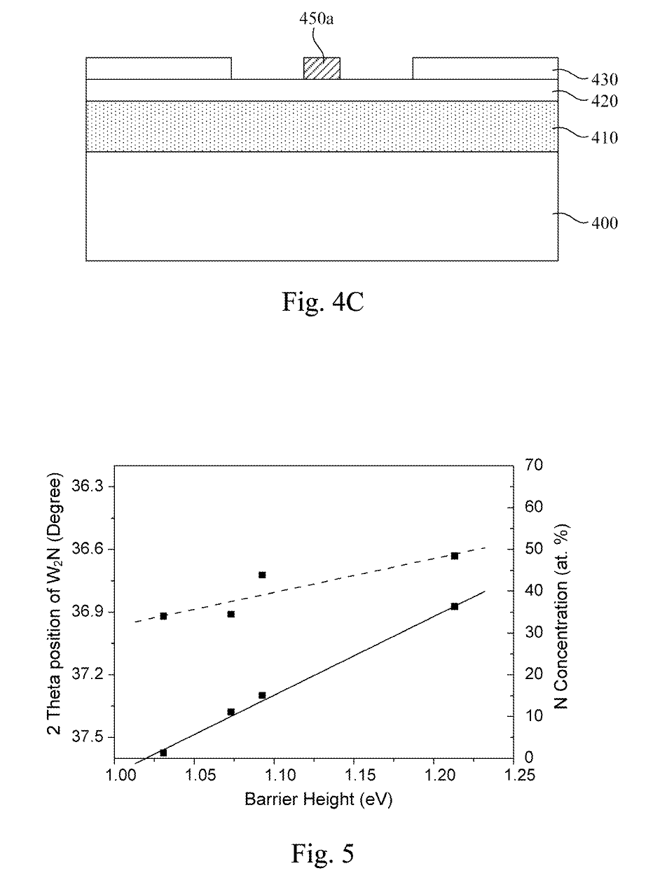

FIGS. 4A-4C are cross-sectional diagrams of a process for fabricating GaN HEMT according to an embodiment of this invention.

In FIG. 4A, a GaN layer 410, an AlGaN layer 420, and source/drain 430 were sequentially formed on a substrate 400. Then, a photoresist layer 440 was formed on the substrate 400 and then patterned to form opening 440a to expose the top surface of the AlGaN layer 420.

In FIG. 4B, the reactive sputtering above was used to form the nitrogen-rich tungsten nitride layer 450a on the AlGaN layer 420 and the nitrogen-rich tungsten nitride layer 450b on the photoresist layer 440.

Finally in FIG. 4C, the photoresist layer 440 and the nitrogen-rich tungsten nitride layer 450b thereon were removed to leave the nitrogen-rich tungsten nitride layer 450a as a Schottky gate of the GaN HEMT.

Measurement Of The Schottky Barrier Height

A measurement of the Schottky barrier height of the GaN HEMT in FIG. 4C was performed. FIG. 5 is a diagram showing the relationship between the nitrogen content of the tungsten nitride gate and the Schottky barrier height of the GaN HEMT. In FIG. 5, the dotted line represent the regression line of the nitrogen content corresponding to the right vertical axis, and the real line is the regression line of the XRD angles corresponding to the left vertical axis marked by 2 theta position.

From FIG. 2, the XRD peaks shifted to lower angles when the nitrogen content of the tungsten nitride is higher. Therefore in FIG. 5, the nitrogen content of the right vertical axis is larger when the 2 theta position of the left vertical axis is smaller. From FIG. 5, the Schottky barrier height is higher when the nitrogen content is higher to reduce the current leakage of the GaN HEMT.

Aging Test

Next, aging test was performed for the GaN HEMT in FIG. 4C. Since the gate of the HEMT in FIG. 4C was Schottky contact, no gate current occurred when a negative bias was applied on the gate under a condition of normal operation. However, there are two situations that can turn on the Schottky gate of the GaN HEMT. First is when the input RF power is too large and the device is pushed into saturation, the Schottky gate of the GaN HEMT will be turned on. Second is when a positive bias is applied on the gate of the GaN HEMT to result in the turn on of this Schottky gate.

HEMTs having a nitrogen-rich tungsten nitride gate in FIG. 4C or Ni/Au gate were aging to compare the aging results. In the aging test, a positive bias were applied on the gate turn on the gate for 24 hours, and the gate current density was fixed at 1 A/mm. Then, the drain current after turning on the HEMTs having a nitrogen-rich tungsten nitride gate or Ni/Au gate under various fixed gate voltage were measured. During the test, various constant voltage (0-4 V) were applied on the gate and the drain voltage (V_{ds}) was slowly increased to measure the drain current (I_{d}).

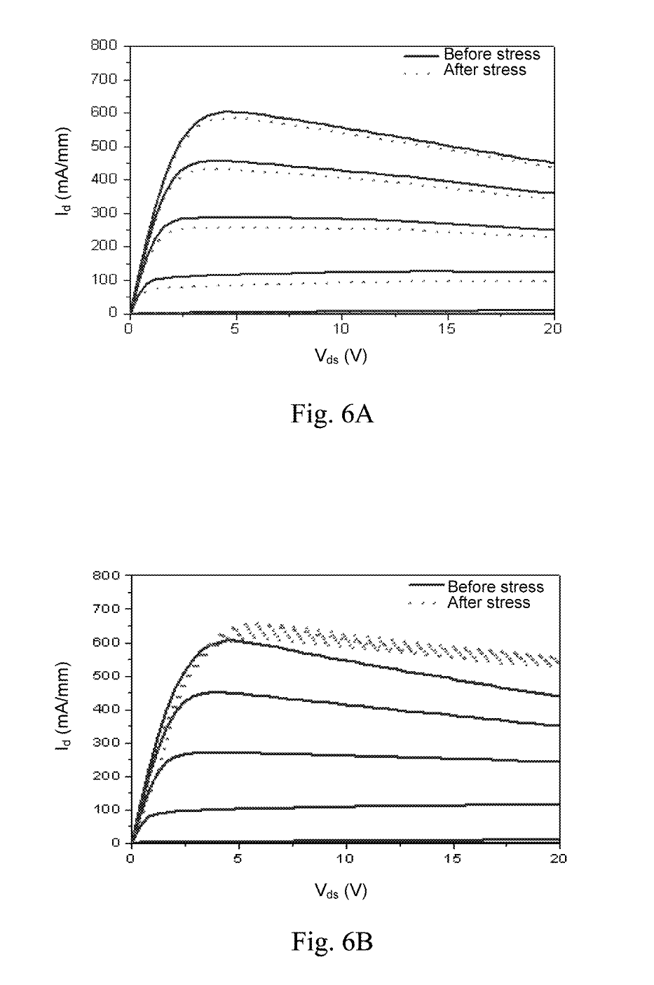

FIGS. 6A-6B are diagrams showing the aging test's result of the HEMTs having a nitrogen-rich tungsten nitride gate or Ni/Au gate under the test conditions described above. The real line represents the I_{d}-V_{ds} curve of the HEMT before aging, and the dotted line represents the I_{d}-V_{ds} curve of the HEMT after aging for 24 hours.

In FIG. 6A, the dotted lines are very close to the corresponding real lines, respectively. It can be seen that the drain current of the HEMT having nitrogen-rich tungsten nitride gate was decreased for only 3% after aging for 24hours. Therefore, the gate's control ability on the drain current was not obviously changed. It means that the electrical property of the HEMT was not obviously changed.

Oppositely, in FIG. 6B, the dotted lines are all crowded together and far away from the corresponding real line. The phenomenon indicated that the Ni/Au gate had lost the control ability on the drain current after aging for 24 hours. Accordingly, the nitrogen-rich tungsten nitride as the HEMT gate material was proved to be very effective in increasing the HEMT's aging resistance.

Measurement of Thermal Stability

Moreover, the thermal stability of the HEMT having the nitrogen-rich tungsten nitride gate was also tested. The thermal stability can affect the highest working temperature and the design for the heat dissipation. In the thermal stability test, the HEMT was annealed under 600° C. for 1 hour. Then, the relationships of the drain current (I_{d}) and the drain voltage (V_{ds}) were measured under various gate voltage (−4-0 V).

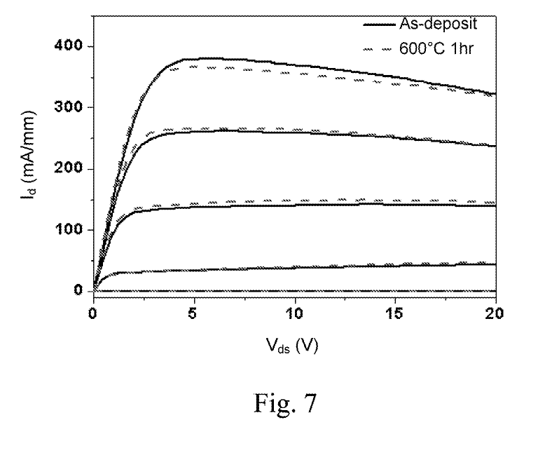

FIG. 7 is the testing result of the thermal stability of the HEMT having the nitrogen-rich tungsten nitride gate under the test conditions described above. The real line represents the HEMT before anneal, and the dotted line represents the HEMT after anneal for 1 hour.

In FIG. 7, the dotted lines are close to the corresponding real lines, respectively. It showed that the nitrogen-rich tungsten nitride material of the HEMT's gate was not discomposed or diffused into the AlGaN/GaN heterostructures to cause the gate sinking problem.

From the various tests above, it can be known that using nitrogen-rich tungsten nitride as the GaN HEMT gate's material can greatly increase the reliability of the GaN HEMT, since the resulted GaN HEMT has good aging resistance and good thermal stability.

The reader's attention is directed to all papers and documents which are filed concurrently with his specification and which are open to public inspection with this specification, and the contents of all such papers and documents are incorporated herein by reference.

All the features disclosed in this specification (including any accompanying claims, abstract, and drawings) may be replaced by alternative features serving the same, equivalent or similar purpose, unless expressly stated otherwise. Thus, unless expressly stated otherwise, each feature disclosed is one example only of a generic series of equivalent or similar features.

What is claimed is:

1. A GaN HEMT having a Schottky gate, the GaN HEMT comprising:
a GaN layer on a substrate;
a AlGaN layer on the GaN layer;
the Schottky gate on the AlGaN layer, wherein the Schottky gate is made by nitrogen-rich tungsten nitride having a nitrogen content of about 0.5 molar ratio; and
a source and a drain on two sides of the nitrogen-rich tungsten nitride gate and on the AlGaN layer.

2. The transistor of claim 1, wherein the nitrogen-rich tungsten nitride is W_{0.52}N_{0.48}.

3. A method of forming a GaN HEMT having a Schottky gate, the method comprising:
forming a GaN layer on a substrate;
forming a AlGaN layer on the GaN layer;
forming a source and a drain on the AlGaN layer and a space existing between the source and the drain; and
forming the Schottky gate between the source and the drain and on the AlGaN layer, wherein the Schottky gate is made by nitrogen-rich tungsten nitride having a nitrogen content of about 0.5 molar ratio.

4. The method of claim 3, wherein the Schottky gate is deposited by reactive sputtering.

5. The method of claim 4, wherein the Schottky gate is deposited with pure nitrogen mixed with argon, and the nitrogen-to-argon (N₂/Ar) gas flow ratio is 0.5.

6. The method of claim 3, wherein the nitrogen-rich tungsten nitride is W_{0.52}N_{0.48}.
